(19) United States
(12) Patent Application Publication
(10) Pub. No.: US 2025/0264547 A1
(43) Pub. Date: Aug. 21, 2025

(54) SYSTEMS, METHODS, AND DEVICES FOR BATTERY MANAGEMENT AND MEASUREMENT

(71) Applicant: Cypress Semiconductor Corporation, San Jose, CA (US)

(72) Inventors: Masashi KIJIMA, Aichi (JP); Hiroyuki MATSUNAMI, Tajimi city (JP); Rajiv SINGH, Bothell, WA (US)

(73) Assignee: Cypress Semiconductor Corporation, San Jose, CA (US)

(21) Appl. No.: 18/581,194

(22) Filed: Feb. 19, 2024

(51) Int. Cl. G01R 31/396; G01R 31/36; G01R 31/3835; G01R 31/385

(52) U.S. Cl. CPC G01R 31/396; G01R 31/3648; G01R 31/3835; G01R 31/386

(57) ABSTRACT

Systems, methods, and devices provide management and measurement of battery cells. Methods include providing, from a signal generator, a first enable signal to a first high voltage interface coupled to a first battery cell, the first enable signal transitioning a first component of the first high voltage interface from a depowered state to a powered state and providing, from the signal generator, a first selection signal to selection logic configured to select the first battery cell for a first measurement operation. Methods also include obtaining, at a processing device, a first voltage measurement from the first battery cell, and deselecting the first battery cell by decoupling the processing device from the first high voltage interface.

### TECHNICAL FIELD

This disclosure relates to battery management, and more specifically, to enhancement of measurements in battery management systems.

### BACKGROUND

Electronic devices may include various power sources which may, for example, include batteries configured to provide power as a power supply. For example, electronic devices may be included in an operational context, such as a vehicle, and may thus be configured to use batteries to store power available for one or more systems of a vehicle, such as an automobile. Batteries may include multiple different battery cells thus enabling configurability of a power supply as well as voltage levels associated with such a power supply. Such batteries may also have associated battery management systems that may be configured to perform various system and management operations, such as obtaining measurements of voltage levels of battery cells so that other components know how much available power is stored in each respective cell. Conventional techniques for making such measurements remain limited because they are inefficient in their implementation of such measurements thus resulting in higher latencies and resource usage.

### BRIEF DESCRIPTION OF THE DRAWINGS

FIG. 1 illustrates a diagram of an example of a battery management system, configured in accordance with some embodiments.

FIG. 2 illustrates a diagram of another example of a battery management system, configured in accordance with some embodiments.

FIG. 3 illustrates a diagram of an example of a high voltage interface device, configured in accordance with some embodiments.

FIG. 4 illustrates an example of a timing diagram of control signals used in a battery management system, in accordance with some embodiments.

FIG. 5 illustrates a diagram of an example of a method for battery management, performed in accordance with some embodiments.

FIG. 6 illustrates a diagram of another example of a method for battery management, performed in accordance with some embodiments.

### DETAILED DESCRIPTION

In the following description, numerous specific details are set forth in order to provide a thorough understanding of the presented concepts. The presented concepts may be practiced without some or all of these specific details. In other instances, well known process operations have not been described in detail so as not to unnecessarily obscure the described concepts. While some concepts will be described in conjunction with the specific examples, it will be understood that these examples are not intended to be limiting.

Battery management systems may be configured to perform a variety of measurement operations for associated battery cells that may be included in a power supply. Such measurements may be used to identify and track voltage levels associated with such battery cells, and to identify when available power from the power supply is getting low. As will be discussed in greater detail below, such battery management systems may sequentially progress through battery cells to obtain measurements from each one. However, conventional techniques for making such measurements are limited because pre-charging operations, also described as wakeup operations, of components may introduce latencies into the measurement process because the battery management system must wait for such pre-charging operations to complete before a measurement may be made. Accordingly, the battery management system may experience additional latencies as well as additional resource usage and power consumption while the battery management system is waiting.

Embodiments disclosed herein provide low-latency measurement operations for battery management systems. As will be discussed in greater detail below, different control signals may be used to independently implement pre-charging operations and selection operations for battery measurement operations. In this way, pre-charging operations may be performed in tandem with other operations, and other components of the battery management system used for obtaining measurements do not have to wait for such pre-charging to occur. Accordingly, embodiments disclosed herein enable the battery management system to obtain measurements with reduced or no latency from pre-charging operations, as well as with reduced resource usage and power consumption due to elimination of such wait times.

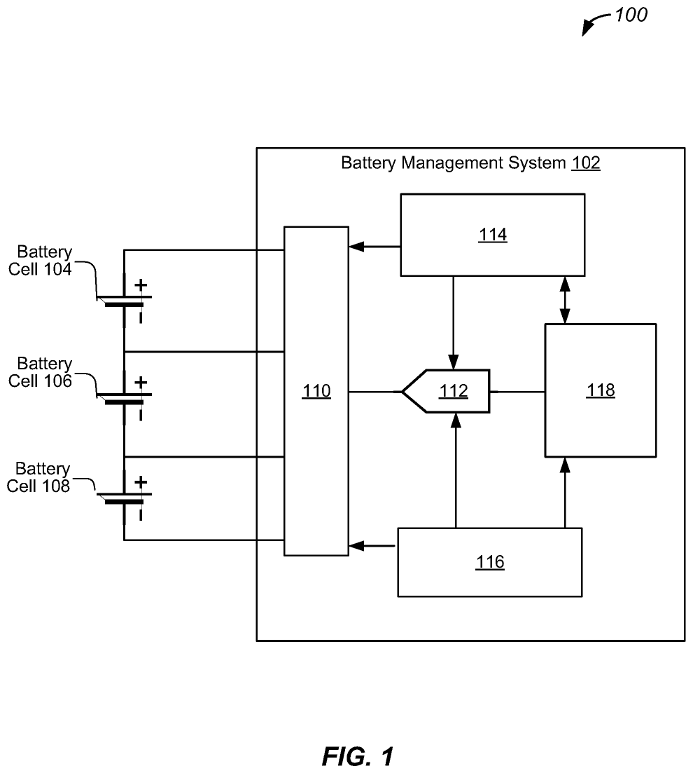

FIG. 1 illustrates a diagram of an example of a battery management system, configured in accordance with some embodiments. In various embodiments, a system, such as system 100, may be configured to generate and provide multiple control signals to components of a battery management system, such as battery management system 102, to reduce latency times in measurements associated with charging of components such as charge pumps, thus improving overall efficiency such battery measurement operations.

Accordingly, system 100 may include battery management system 102 that may be coupled to a power supply that may include multiple battery cells, such as battery cell 104, battery cell 106, and battery cell 108. As shown in FIG. 1, battery cell 104, battery cell 106, and battery cell 108 are coupled in series to collectively provide a power supply for a device or system that includes battery management system 102. As will be discussed in greater detail below, battery management system 102 is configured to periodically and/or dynamically obtain measurements from battery cells to generate measurement data that provides system 100 with information about the current status and power level of each battery cell. Accordingly, battery cells may be independently selected and measured via components such as multiplexer 110 and analog to digital converter (ADC) 112. As will also be discussed in greater detail below, separate control signals may be generated and used for wakeup and selection operations to enable preemptive charging of components of multiplexer 110 prior to selection and measurement operations, thus reducing an effective temporal latency associated with such wakeup operations.

As shown in FIG. 1, inputs from battery cell 104, battery cell 106, and battery cell 108 may be provided to a component of battery management system 102, such as multiplexer 110. As will be discussed in greater detail below, multiplexer 110 is configured to include voltage interface components which provide an interface between components of the battery cells that have higher operational voltages than components of battery management system 102. Multiplexer 110 is coupled to ADC 112 which is coupled to processing device 118. In various embodiments, processing device 118 is configured to generate measurement data based on inputs received from ADC 112. Accordingly, processing device 118 may be configured to receive an output of ADC 112 and generate measurement data based on the output of ADC 112, which may be time series data or an averaged data value, that represents a voltage level of a selected battery cell.

Moreover, battery management system 102 additionally includes signal generator 116 which is configured to generate control signals provided to multiplexer 110. Accordingly, as will be discussed in greater detail below, signal generator 116 is configured to generate and apply a combination of control signals that may perform operations for different components of multiplexer 110 in tandem, thus reducing an overall temporal latency associated with such operations. Battery management system 102 may also include memory 114 which may be configured to store one or more configuration and/or reference values used by other components of battery management system 102 as well as various measurement data obtained through measurements disclosed herein.

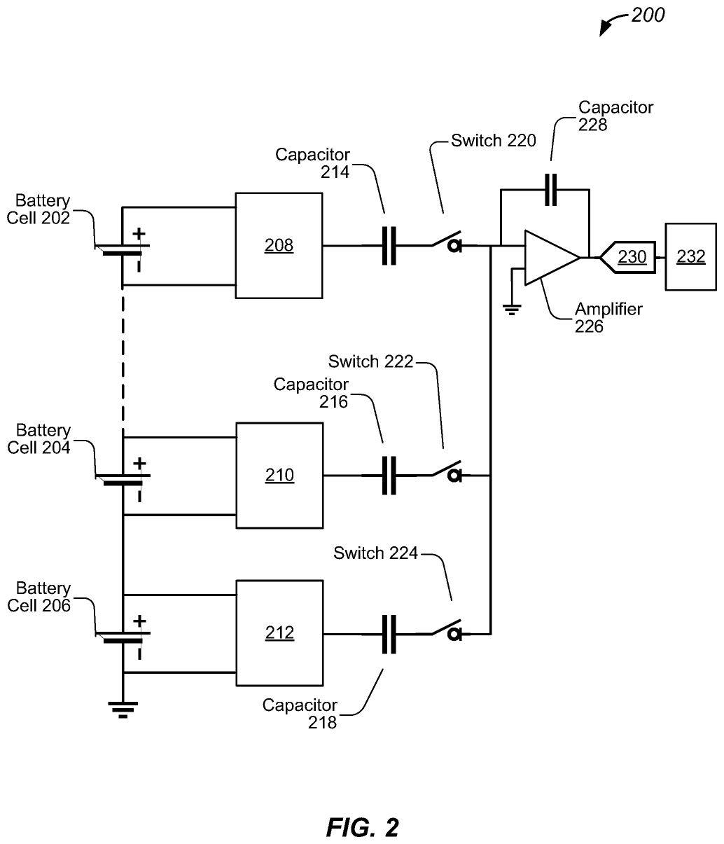

FIG. 2 illustrates a diagram of another example of a battery management system, configured in accordance with some embodiments. In various embodiments, a system, such as system 200, may be configured to generate and provide multiple control signals to components of a battery management system to reduce latency associated with charging of components, such as charge pumps, thus improving overall efficiency such battery measurement operations. As will be discussed in greater detail below, multiple high voltage interfaces may be used to facilitate measurements of battery cells, and multiple control signals may be used to pre-charge components prior to such measurement operations.

In various embodiments, system 200 includes various battery cells, such as battery cell 202, battery cell 204, and battery cell 206. As shown in FIG. 2, battery cell 202, battery cell 204, and battery cell 206 are coupled in series to collectively provide a power supply for a device or system that includes system 200. As similarly discussed above, system 200 is configured to periodically and/or dynamically obtain measurements from battery cells to generate measurement data that provides system 200 with information about the current status and power level of each battery cell. Accordingly, battery cells may be independently selected and measured via components such as high voltage interfaces and ADC 230 and associated processing logic, such as processing logic included in processing device 232.

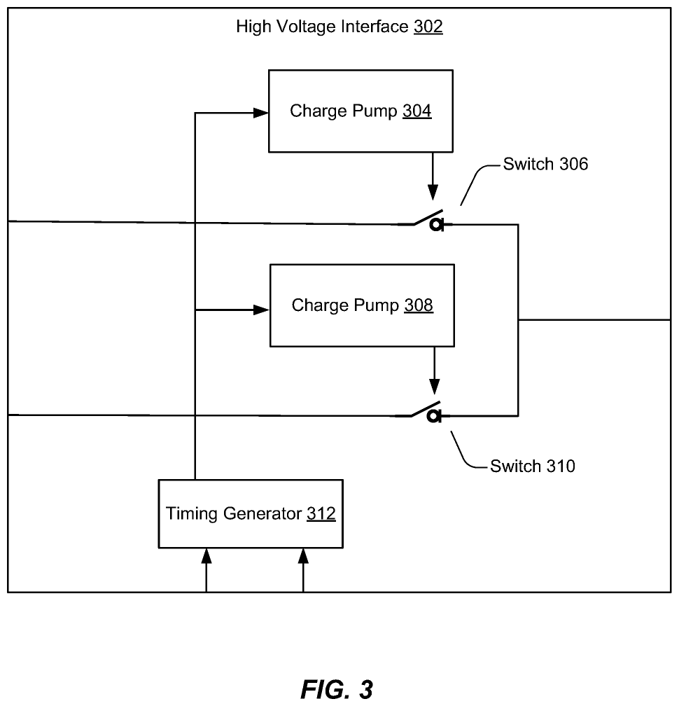

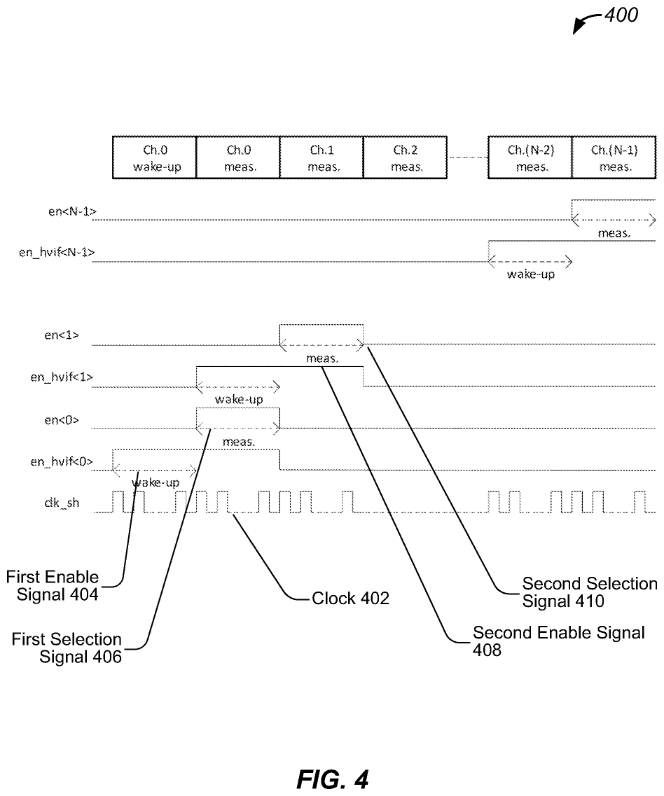

More specifically, each battery cell may have an associated high voltage interface module, such as high voltage interface 208, high voltage interface 210, and high voltage interface 212. Such high voltage interfaces may be included in a component, such as a multiplexer. Each high voltage interface may be coupled to both a positive terminal and a negative terminal of its associated battery cell. In this way, a high voltage interface may facilitate coupling and measurement of a voltage at each terminal when such selections are made via a configuration of one or more switches, as will be discussed in greater detail below with reference to FIG. 3 and FIG. 4. Moreover, such selection of high voltage interfaces and associated battery cells may be implemented in a round-robin manner that cycles from top to bottom, bottom to top, or in any suitable order.

In various embodiments, each high voltage interface is configured to receive a control signal which may be an enable signal configured to activate one or more components of the high voltage interface. As will be discussed in greater detail below, each high voltage interface may include a component, such as a charge pump, which is charged prior to measurement operations are performed. Accordingly, a high voltage interface may receive an enable signal prior to it being selected for a measurement operation, thus eliminating latency associated with such charging during the measurement operation. Moreover, enabling of the high voltage interfaces may be managed such that measurement operations of different high voltage interfaces may be performed sequentially and without such charging-related latency periods.

In various embodiments, control signals provide to the high voltage interfaces, such as enable signals and selection signals, are implemented independently of control signals used for ADC 230 and its associated processing logic. Accordingly, the high voltage interfaces may be powered and depowered independent of ADC 230 and via a separate set of control signals, thus allowing enabling of the high voltage interfaces even while ADC 230 is depowered. Similarly, selection signals for switches may also be generated and provided independent of control of ADC 230. In this way, ADC 230 may be depowered when not in use, and overall power consumption of system 200 is reduced.

As shown in FIG. 2, system 200 additionally includes output capacitors, such as capacitor 214, capacitor 216, and capacitor 218. Moreover, such capacitors are coupled to switches, such as switch 220, switch 222, and switch 224. In various embodiments, the switches are coupled to an input of an amplifier, such as amplifier 226, which may have a feedback capacitor, such as capacitor 228, and may provide an input to ADC 230. In this way an output of a high voltage interface may be provided to ADC 230.

As will be discussed in greater detail below, switches may be provided with another set of control signals which are used to control selection and deselection of high voltage interfaces coupled to the switches. More specifically, the set of control signals received by the switches may be selection signals used to select a particular battery cell for measurement via its associated high voltage interface. As will be discussed in greater detail below with reference to FIG. 4, the selection signals may be implemented independently of the control signals received by the high voltage interfaces.

Moreover, the control signals received by the high voltage interfaces, which may be “enable” signals, may be configured to implement a designated wake period prior to selections identified by the control signals received by the switches, which may be selection signals. In various embodiments, such a designated wake period may be determined by an entity, such as a user or manufacturer. In various embodiments, the entity may determine parameters for the wake period based on expected operational conditions of the high voltage interfaces. For example, the designated wake period may have a duration determined based on an expected operational temperature of the high voltage interface as well as expected battery cell voltages coupled to the high voltage interfaces. Accordingly, one or more parameters of the wake period, such as a duration, may be static and predetermined by such an entity, and stored as one or more data values within a memory of a battery management system. In some embodiments, such static parameters may be determined based on a designated latency parameter that may be specified by a user.

In some embodiments, the one or more parameters of the wake period may be determined dynamically. For example, a time and amount of charging applied to a high voltage interface may be temperature dependent. Accordingly, a duration of the wake period may be determined dynamically based on one or more temperature measurements made within system 200, such as one or more components configured to obtain chip temperature measurements for an integrated circuit in which system 200 is implemented. In this way, the duration of the wake period and parameters of the enable signals may be determined dynamically based on one or more operational and/or system parameters, such as a temperature of one or more components.

It will be appreciated that while FIG. 2 illustrates multiple switches being used to provide output signals to ADC 230, in some embodiments, each high voltage interface may have its own ADC. Accordingly, instead of switches coupled to outputs of the high voltage interfaces, a plurality of ADCs may be coupled and selectively enabled and depowered via a separate set of control signals based on when measurement operations are implemented. Accordingly, each ADC may be independently enabled when its associated battery cell is to be measured, and depowered when not in use.

FIG. 3 illustrates a diagram of an example of a high voltage interface device, configured in accordance with some embodiments. As discussed above, a multiplexer may include various high voltage interfaces, such as high voltage interface 302. As shown in FIG. 3, high voltage interface 302 includes two inputs that may be received from a positive and negative terminal of a battery cell. The inputs may be coupled to charge pump 304 and charge pump 308 via switch 306 and switch 310, respectively. Moreover, high voltage interface 302 includes timing generator 312 which is configured to receive a control signal as well as a clock signal. Thus, the control signal may be provided to charge pump 304 and charge pump 308 via timing generator 312, and the control signal may be provided synchronously based on the clock signal. In various embodiments, the control signal is a high voltage interface enable signal that activates charge pump 304 and charge pump 308. As will be discussed in greater detail below with reference to FIG. 4, such a signal may wakeup charge pump 304 and charge pump 308 prior to selection and measurement operations for their associated battery cell, thus making them immediately available for such selection and measurement operations and reducing a temporal latency associated with such wakeup operations from the perspective of the battery management system.

In various embodiments, switch 306 and switch 310 are analog switches that are controlled by charge pump 304 and charge pump 308 respectively. Accordingly, signals provided to charge pump 304 and charge pump 308 are used to control operation of switch 306 and switch 310, and control selection of an input provided to high voltage interface 302. For example, a designated sequence of operations may be performed in which charge pump 304 closes switch 306 to select a first terminal of a battery cell for a first measurement, and subsequently opens switch 306 so that charge pump 308 may close switch 310 to select a second terminal of the battery cell for a second measurement. The outputs may be provided to additional components, such as an ADC and processing logic that may compute a difference of the measurements to determine the voltage of the batter cell.

FIG. 4 illustrates an example of a timing diagram of control signals used in a battery management system, in accordance with some embodiments. As similarly discussed above, several control signals may be used to manage wakeup operations and selection operations for battery measurement operations. In various embodiments, a clock signal, such as clock 402, may be used for timing and synchronization of signal transitions. Moreover, first enable signal 404 may be provided to a first high voltage interface, and used to initiate charging of one of more components of the first high voltage interface, such as a first charge pump. Furthermore, first selection signal 406 may be provided to a first switch coupled to an output of the first high voltage interface, thus selecting the first high voltage interface for a measurement operation. As shown in FIG. 4, first enable signal 404 beings prior to first selection signal 406 by a designated temporal offset or duration of time also referred to as a wake period. As discussed above, such a duration of time may be a designated amount of time or may be dynamically determined.

Moreover, second enable signal 408 may be provided to a second high voltage interface to initiate charging of one of more components of the second high voltage interface, such as a second charge pump. Furthermore, second selection signal 410 may be provided to a second switch coupled to an output of the second high voltage interface, thus selecting the second high voltage interface for a measurement operation.

As shown in FIG. 4, second enable signal 408 is provided to the second high voltage interface while the first measurement operation is being performed. Accordingly, implementation of separate and independent control signals for high voltage interfaces and selection switches enables parallel implementation of measurement operations and wakeup operations for different high voltage interfaces, and reduces latencies that would otherwise occur if such operations were serialized. As similarly discussed above, the enable signals and selection signals shown in FIG. 4 are generated and provided independent of control signals used for an associated ADC. Accordingly, enabling and selection operations may be performed independent of enabling and depowering of the ADC and its associated processing logic.

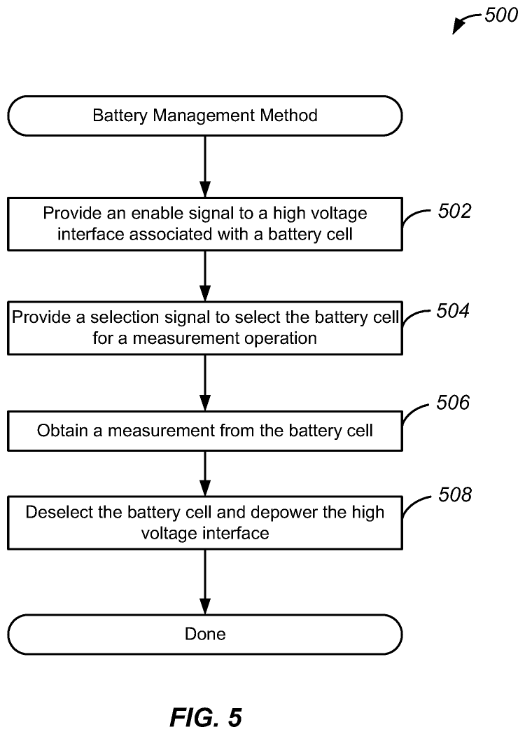

FIG. 5 illustrates a diagram of an example of a method for battery management, performed in accordance with some embodiments. In various embodiments, a method, such as method 500, may be performed to generate and provide multiple control signals to components of a battery management system to reduce latency associated with charging of components, such as charge pumps, thus improving overall efficiency such battery measurement operations. As will be discussed in greater detail below, independent control signals may be used for high voltage interfaces and selection switches to pre-charge components prior to measurement operations.

Method 500 may perform operation 502 during which an enable signal may be provided to a high voltage interface associated with a battery cell. As discussed above, the battery cell may be identified for an upcoming measurement operation, and one or more components of the high voltage interface may be provided with an enable signal to provide them with power so that they may charge up to prepare for the measurement operation. Such a period of preparing the high voltage interface may also be described as a wake period in which one or more components of the high voltage interface transition from a depowered state to a powered state.

Method 500 may perform operation 504 during which a selection signal may be provided to select the battery cell for a measurement operation. Accordingly, the selection signal may configure coupling between the high voltage interface and a measurement component, such as an ADC and associated processing logic, to couple an output of the high voltage interface to the ADC thus enabling the ADC to receive the output signal. Accordingly, once selected, the ADC may be coupled to the battery cell via the high voltage interface.

Method 500 may perform operation 506 during which a measurement may be obtained from the battery cell. Accordingly, as similarly discussed above, the ADC and its associated processing logic may store measurement data generated based on an output of the ADC, and such measurement data may be stored in memory as well as various other identifiers and metadata. For example, the measurement data may be stored with a unique identifier that identifies the battery cell as well as metadata, such as a timestamp.

Method 500 may perform operation 508 during which the battery cell may be deselected, and the high voltage interface may be disabled. Accordingly, the enable signal and the select signal may be canceled, thus depowering the one or more components of the high voltage interface, and decoupling the high voltage interface from the ADC. In this way, selection and operation of the high voltage interface may be managed independently, and as will be discussed in greater detail below, may be parallelized with selection and operation of other high voltage interfaces.

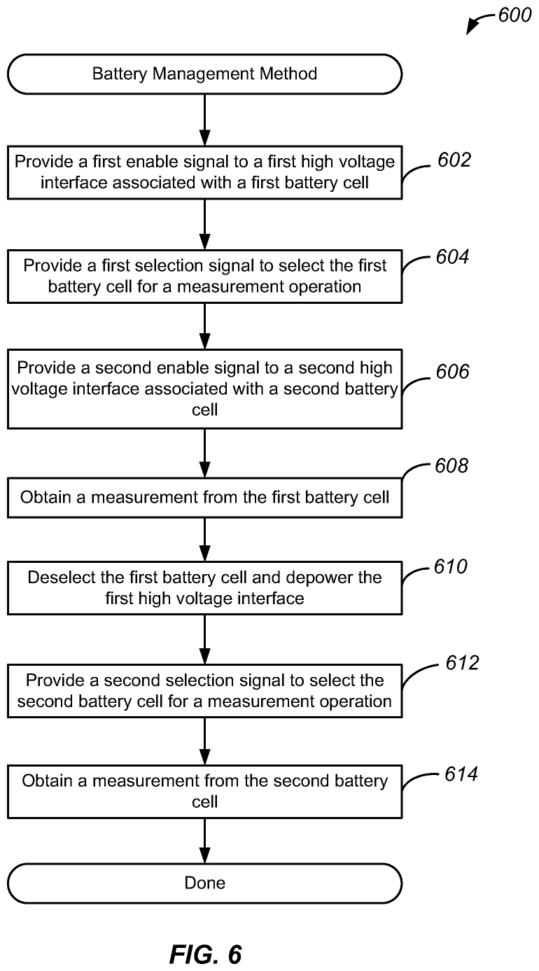

FIG. 6 illustrates a diagram of another example of a method for battery management, performed in accordance with some embodiments. In various embodiments, a method, such as method 600, may be performed to generate and provide multiple control signals to components of a battery management system to reduce latency associated with charging of components, such as charge pumps, thus improving overall efficiency such battery measurement operations. As will be discussed in greater detail below, independent control signals may be used for multiple high voltage interfaces and switches to manage measurement operations and parallelize wakeup operations across multiple high voltage interfaces associated with multiple measurement operations.

Method 600 may perform operation 602 during which a first enable signal may be provided to a first high voltage interface associated with a first battery cell. As similarly discussed above, the first battery cell may be identified for an upcoming measurement operation, and one or more components of the first high voltage interface may be provided with a first enable signal to provide them with power so that they may charge up to prepare for the measurement operation. In some embodiments, the first enable signal may be provided to a first charge pump included in the first high voltage interface to transition the first charge pump from a depowered state to a powered state.

Method 600 may perform operation 604 during which a first selection signal may be provided to select the first battery cell for a measurement operation. Accordingly, the first selection signal may configure coupling between the first high voltage interface and a measurement component, such as an ADC and associated processing logic, to couple an output of the first high voltage interface to the ADC thus enabling the ADC to receive the output signal. In various embodiments, the coupling may be performed by selection logic, such as a first switch. Accordingly, the first switch may receive the first selection signal and may toggle to a closed state in which the ADC is coupled to the output of the first high voltage interface.

Method 600 may perform operation 606 during which a second enable signal may be provided to a second high voltage interface associated with a second battery cell. As similarly discussed above, the second battery cell may be identified for an upcoming additional measurement operation as a measurement procedure progresses through measurements of all battery cells. Accordingly, one or more components of the second high voltage interface may be provided with the second enable signal to provide them with power so that they may charge up to prepare for the additional measurement operation. As similarly discussed above, the second enable signal may be provided to a second charge pump included in the second high voltage interface to transition the second charge pump from a depowered state to a powered state.

Method 600 may perform operation 608 during which a measurement may be obtained from the first battery cell. Accordingly, as similarly discussed above, the first high voltage interface may be coupled to both terminals of the first battery cell, and may provide coupling to facilitate a measurement of each terminal by the ADC and its associated processing logic. The measurements of the terminal voltages may be used to compute a first voltage measurement for the first battery cell, and the first voltage measurement may be stored in memory. As previously described with reference to FIG. 4, it will be appreciated that an onset of operation 606 and operation 608 may occur concurrently, or one may occur before the other. The timing of operation 606 and operation 608 may be determined based on a first duration of time used for the measurement operation, as well as a second duration of time used for the wakeup period for the second high voltage interface. In this way, the measurement operation for the first battery cell and the wakeup period for the second high voltage interface may be performed in parallel and independently.

Method 600 may perform operation 610 during which the first battery cell may be deselected, and the first high voltage interface may be depowered. Accordingly, the first enable signal may be canceled to depower the first charge pump, and the first selection signal may be canceled to decouple the first high voltage interface from the ADC. It will be appreciated that the canceling of the first enable signal and the first selection signal may occur after the assertion of the second enable signal. In this way, wakeup operations for high voltage interfaces may be parallelized with other measurement operations, and such parallelization may be managed via independent control signals, such as enable signals and selections signals. Accordingly, measurement operations performed by the ADC and associated processing logic may occur sequentially and without latencies and delays due to wakeup operations, as shown above in FIG. 4, and processing time and power consumption by ADC and associated processing logic is also reduced.

Method 600 may perform operation 612 during which a second selection signal may be provided to select the second battery cell for a measurement operation. The second selection signal may configure coupling between the second high voltage interface and the ADC and associated processing logic to couple an output of the second high voltage interface to the ADC thus enabling the ADC to receive the output signal. In various embodiments, the coupling may be performed by selection logic, such as a second switch. Accordingly, the second switch may receive the second selection signal and may toggle to a closed state in which the ADC is coupled to the output of the second high voltage interface.

Method 600 may perform operation 614 during which a measurement may be obtained from the second battery cell. Accordingly, as similarly discussed above, the second high voltage interface may be coupled to both terminals of the second battery cell, and may provide coupling to facilitate a measurement of each terminal by the ADC and its associated processing logic. The measurements of the terminal voltages may be used to compute a second voltage measurement for the second battery cell, and the second voltage measurement may be stored in memory.

It will be appreciated that if additional battery cells are to be measured, additional enable and select signals may also be used. For example, if a third battery cell is to be measured, a third enable signal may be provided to a third high voltage interface prior to and/or in parallel with operation 614 discussed above. Moreover, the second enable signal and the second selection signal may subsequently be canceled, and additional iterations of method 600 may be performed if additional battery cells should be measured, such as a third battery cell.

Although the foregoing concepts have been described in some detail for purposes of clarity of understanding, it will be apparent that certain changes and modifications may be practiced within the scope of the appended claims. It should be noted that there are many alternative ways of implementing the processes, systems, and devices. Accordingly, the present examples are to be considered as illustrative and not restrictive.

What is claimed is:

1. A method comprising:
providing, from a signal generator, a first enable signal to a first high voltage interface coupled to a first battery cell, the first enable signal transitioning a first component of the first high voltage interface from a depowered state to a powered state;
providing, from the signal generator, a first selection signal to selection logic configured to select the first battery cell for a first measurement operation;
obtaining, at a processing device, a first voltage measurement from the first battery cell; and
deselecting the first battery cell by decoupling the processing device from the first high voltage interface.

2. The method of claim 1, wherein the first component comprises a charge pump.

3. The method of claim 1 further comprising:
providing, from the signal generator, a second enable signal to a second high voltage interface coupled to a second battery cell, the second enable signal transitioning a second component of the second high voltage interface from a depowered state to a powered state.

4. The method of claim 3, wherein the providing of the second enable signal occurs prior to cancellation of the first selection signal.

5. The method of claim 3 further comprising:
providing a second selection signal to selection logic configured to select the second battery cell for a second measurement operation.

6. The method of claim 5 further comprising:
obtaining, at the processing device, a second voltage measurement from the second battery cell.

7. The method of claim 1, wherein a duration of the first enable signal is determined by a user.

8. The method of claim 1, wherein a duration of the first enable signal is dynamically configurable based on one or more operational parameters.

9. The method of claim 1, wherein an output of the first high voltage interface is provided to the processing device via an analog to digital converter (ADC), and wherein the ADC is controlled via a separate set of control signals than the first enable signal and the first selection signal.

10. A system comprising:
a first high voltage interface configured to be coupled to a first battery cell;
a processing device configured to perform a first measurement operation to obtain a first voltage measurement from the first battery cell;
first selection logic configured to couple the first high voltage interface to the processing device; and
a signal generator configured to:
provide a first enable signal to the first high voltage interface, the first enable signal transitioning a first component of the first high voltage interface from a depowered state to a powered state; and
provide a first selection signal to the first selection logic to select the first battery cell for the first measurement operation.

11. The system of claim 10, wherein the first component comprises a charge pump.

12. The system of claim 10, wherein the signal generator is further configured to:
provide a second enable signal to a second high voltage interface coupled to a second battery cell, the second enable signal transitioning a second component of the second high voltage interface from a depowered state to a powered state, and wherein the providing of the second enable signal occurs prior to cancellation of the first selection signal.

13. The system of claim 12, wherein the signal generator is further configured to:
provide a second selection signal to selection logic configured to select the second battery cell for a second measurement operation.

14. The system of claim 10, wherein a duration of the first enable signal is determined by a user or is dynamically configurable based on one or more operational parameters.

15. The system of claim 10, wherein an output of the first high voltage interface is provided to the processing device via an analog to digital converter (ADC), and wherein the ADC is controlled via a separate set of control signals than the first enable signal and the first selection signal.

16. A device comprising:
a first high voltage interface configured to be coupled to a first battery cell;
first selection logic configured to couple the first high voltage interface to a processing device configured to perform a first measurement operation to obtain a first voltage measurement from the first battery cell; and
a signal generator configured to:
provide a first enable signal to the first high voltage interface, the first enable signal transitioning a first component of the first high voltage interface from a depowered state to a powered state; and
provide a first selection signal to the first selection logic to select the first battery cell for the first measurement operation.

17. The device of claim 16, wherein the first component comprises a charge pump.

18. The device of claim 16, wherein the signal generator is further configured to:
provide a second enable signal to a second high voltage interface coupled to a second battery cell, the second enable signal transitioning a second component of the second high voltage interface from a depowered state to a powered state, and wherein the providing of the second enable signal occurs prior to cancellation of the first selection signal.

19. The device of claim 18, wherein the signal generator is further configured to:
provide a second selection signal to second selection logic configured to select the second battery cell for a second measurement operation.

20. The device of claim 16, wherein an output of the first high voltage interface is provided to the processing device via an analog to digital converter (ADC), and wherein the ADC is controlled via a separate set of control signals than the first enable signal and the first selection signal.
